(19) United States
(12) Patent Application Publication
(10) Pub. No.: US 2010/0109148 A1
(43) Pub. Date: May 6, 2010

(54) SEMICONDUCTOR DEVICE

(75) Inventors: Kunihiro Yamashita, Tokyo (JP); Kazushi Hatauchi, Tokyo (JP); Naoki Izumi, Tokyo (JP); Akira Yamazaki, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/604,385

(22) Filed: Oct. 22, 2009

(30) Foreign Application Priority Data
Oct. 31, 2008 (JP) 2008-281171

(51) Int. Cl. H01L 23/495; H01L 23/31

(52) U.S. Cl. 257/692; 257/666; 257/E23.124; 257/E23.031

(57) ABSTRACT

When a second semiconductor chip is mounted onto a first semiconductor chip, collision of the first semiconductor chip with a lead frame is to be prevented. The lead frame has a die pad and suspending leads for supporting the die pad. A joining portion is provided over the lead frame. The first semiconductor chip is provided over the lead frame through the joining portion. The second semiconductor chip is provided over the first semiconductor chip. A resin member covers the die pad and the first and second semiconductor chips. The joining portion is positioned over each of the die pad and the suspending leads.

### CROSS-REFERENCE TO RELATED APPLICATIONS

The disclosure of Japanese Patent Application No. 2008-281171 filed on Oct. 31, 2008 including the specification, drawings and abstract is incorporated herein by reference in its entirety.

### BACKGROUND OF THE INVENTION

The present invention relates to a semiconductor device having plural semiconductor chips and a lead frame.

Heretofore there has been known a method wherein a semiconductor chip is bonded to a die pad having a plane area larger than that of the semiconductor chip through a film having about the same plane area as that of the die pad.

Recently, due to the reduction of cost and restrictions on the device, there has been a growing need for paste die bonding which uses paste instead of film. When paste is applied to the whole surface of a semiconductor chip in paste die bonding, there may occur peeling or chip cracking due to a difference in heat shrinkage between a lead frame and the chip in a reflow process. For avoiding this inconvenience it is necessary to make the paste application area small. To this end there is used a die pad having a plane area smaller than that of the semiconductor chip. Such a technique is disclosed, for example, in Japanese Unexamined Patent Publication Nos. 2005-354117 (Patent Literature 1), Hei 10 (1998)-12797 (Patent Literature 2) and 2004-146853 (Patent Literature 3).

Recently, moreover, an SiP (System in Package) type with plural semiconductor chips mounted within one package has been becoming more and more popular. There is not only a case where such plural chips are disposed on the same plane but also a case where they are stacked. In the case of such a stacked structure, a first semiconductor chip is first die-bonded onto a die pad and then a second semiconductor chip is mounted onto the first semiconductor chip.

### [Patent Literature 1]

Japanese Unexamined Patent Publication No. 2005-354117
(FIGS. 15 and 16)

### [Patent Literature 2]

Japanese Unexamined Patent Publication No. Hei 10 (1998)-12797
(FIG. 6)

### [Patent Literature 3]

Japanese Unexamined Patent Publication No. 2004-146853
(FIG. 1)

### SUMMARY OF THE INVENTION

In connection with the above stacked structure there sometimes is a case where the center of the first semiconductor chip and that of the second semiconductor chip are offset from each other for some reason in design. In this case, as noted above, if there is used a die pad having a plane area smaller than that of the first semiconductor chip, the support of the first semiconductor chip by the die pad is apt to become unstable. As a result, the first semiconductor chip may tilt under a load imposed thereon in a mounting process of the second semiconductor chip, with consequent collision of the first semiconductor chip with the lead frame, thus giving rise to the problem that there may occur cracking or chipping of the semiconductor chip.

The present invention has been accomplished in view of the above-mentioned problem and it is an object of the invention to provide a semiconductor device capable of preventing collision of a first semiconductor chip with a lead frame when a second semiconductor chip is mounted on the first semiconductor chip.

A semiconductor device according to one aspect of the present invention comprises a lead frame, a joining portion, first and second semiconductor chips, and a resin member. In this semiconductor device, the lead frame includes a die pad and suspending leads for supporting the die pad. The joining portion is provided over the lead frame. The first semiconductor chip is provided over the lead frame through the joining portion. The second semiconductor chip is provided over the first semiconductor chip. The resin member covers the die pad and the first and second semiconductor chips. The joining portion is positioned over the die pad and the suspending leads.

A semiconductor device according to another aspect of the present invention comprises a lead frame, a joining portion, first and second semiconductor chips, and a resin member. In this semiconductor device, the lead frame includes a die pad and suspending leads for supporting the die pad. The joining portion is provided over the lead frame. The first semiconductor chip is provided over the lead frame through the joining portion, further, when seen in plan, has a first center line and is disposed so as to overlap the die pad and partially overlap the suspending leads. The second semiconductor chip is provided over the first semiconductor chip and, in plan view, has a second center line parallel to the first center line and positioned on one side of the first center line. The resin member covers the die pad and the first and second semiconductor chips. The joining portion is positioned on both sides of the second center line in plan view.

According to the above one aspect, since not only the joining portion lying over the die pad but also the joining portion lying over the suspending leads can support the first semiconductor chip, the first semiconductor chip is supported stably, whereby tilting of the first semiconductor chip is suppressed when the second semiconductor chip is mounted over the first semiconductor chip. Consequently, it is possible to prevent cracking or chipping of the first semiconductor chip caused by collision of the first semiconductor chip with the lead frame.

According to another aspect described above, since the joining portion positioned on both sides of the second center line in plan view can support the first semiconductor chip, the first semiconductor chip is supported stably, whereby tilting of the first semiconductor chip is suppressed when the second semiconductor chip is mounted over the first semiconductor chip. Consequently, it is possible to prevent cracking or chipping of the first semiconductor chip caused by collision of the first semiconductor chip with the lead frame.

### BRIEF DESCRIPTION OF THE DRAWINGS

FIG. 1 is a plan view showing schematically the configuration of a semiconductor device according to a first embodiment of the present invention;

FIG. 2 is a schematic enlarged view of a central portion of FIG. 1;

FIG. 3 is a schematic sectional view taken along line III-III in FIG. 1;

FIG. 4 is a schematic sectional view taken along line IV-IV in FIG. 2;

FIG. 5 is a partial plan view showing schematically a first process in a method for manufacturing the semiconductor device according to the first embodiment;

FIG. 6 is a schematic enlarged view of a central portion of FIG. 5;

FIG. 7 is a partial plan view showing schematically a second process in the method for manufacturing the semiconductor device according to the first embodiment;

FIG. 8 is a partial plan view showing schematically a third process in the method for manufacturing the semiconductor device according to the first embodiment;

FIG. 9 is a partial plan view showing schematically a fourth process in the method for manufacturing the semiconductor device according to the first embodiment;

FIG. 10 is a partial plan view showing schematically a fifth process in the method for manufacturing the semiconductor device according to the first embodiment;

FIG. 11 is a schematic sectional view taken along line XI-XI in FIG. 10;

FIG. 12 is a schematic sectional view showing schematically one process in a method for manufacturing a semiconductor device as a comparative example;

FIG. 13 is a sectional view showing schematically the configuration of a semiconductor device according to a second embodiment of the present invention;

FIG. 14 is a schematic partial plan view showing one process in a method for manufacturing the semiconductor device according to the second embodiment;

FIG. 15 is a partial sectional view showing schematically the configuration of a semiconductor device according to a third embodiment of the present invention;

FIG. 16 is a partial plan view showing schematically a first process in a method for manufacturing the semiconductor device according to the third embodiment;

FIG. 17 is a partial plan view showing schematically a second process in the method for manufacturing the semiconductor device according to the third embodiment;

FIG. 18 is a partial plan view showing schematically a third process in the method for manufacturing the semiconductor device according to the third embodiment;

FIG. 19 is a partial plan view showing schematically a fourth process in the method for manufacturing the semiconductor device according to the third embodiment; and

FIG. 20 is a partial plan view showing schematically a fifth process in the method for manufacturing the semiconductor device according to the third embodiment.

### DETAILED DESCRIPTION OF THE PREFERRED EMBODIMENTS

Embodiments of the present invention will be described below with reference to the drawings.

### First Embodiment

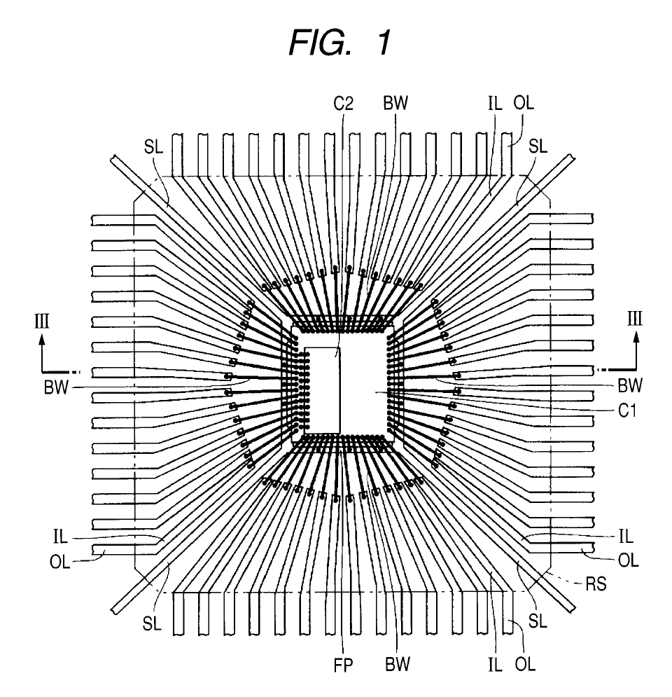

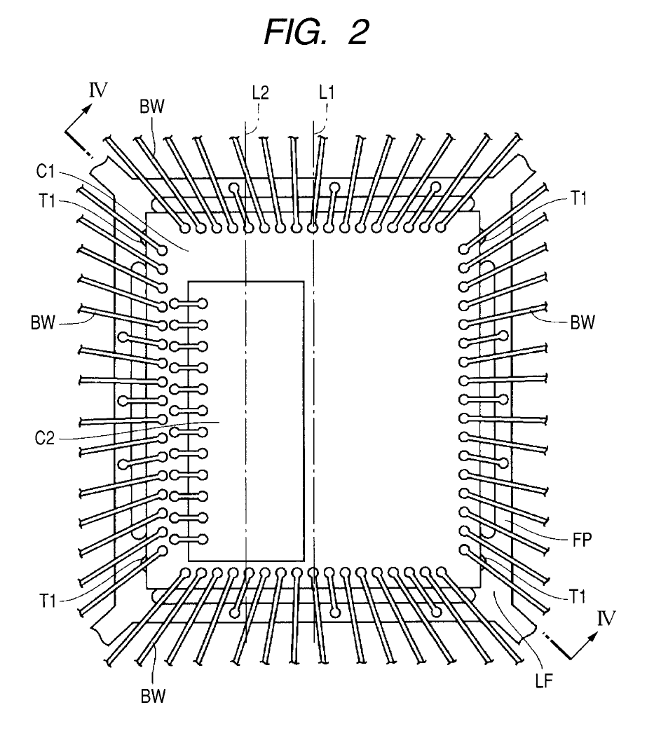

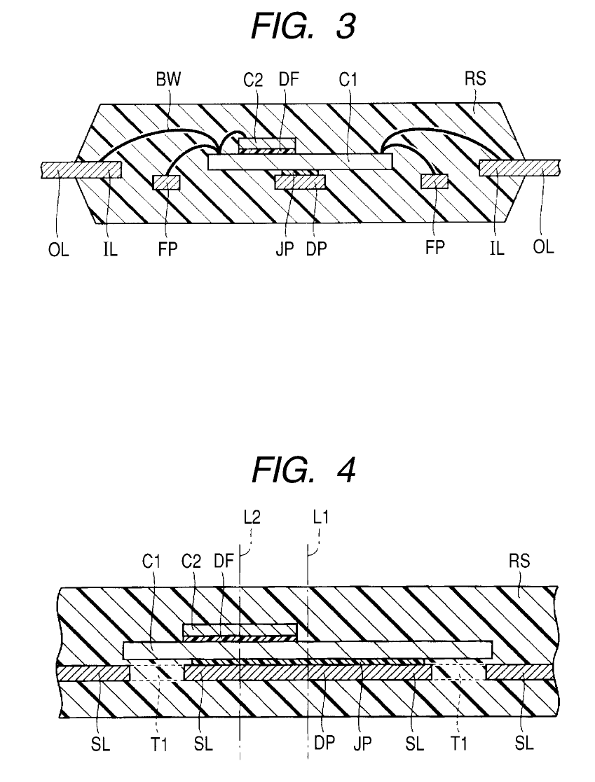

FIG. 1 is a plan view showing schematically the configuration of a semiconductor device according to a first embodiment of the present invention. FIG. 2 is a schematic enlarged view of a central portion of FIG. 1. FIG. 3 is a schematic sectional view taken along line III-III in FIG. 1. FIG. 4 is a schematic sectional view taken along line IV-IV in FIG. 2. In FIG. 1, outer edges alone of a resin member are indicated by a dash-double dot line.

Referring to FIGS. 1 to 4, the semiconductor device of this first embodiment includes a lead frame, a paste portion JP, a lower semiconductor chip C1 (a first semiconductor chip), an upper semiconductor chip C2 (a second semiconductor chip), a resin member RS, a die attach film DF, and bonding wires BW.

The lead frame includes a die pad DP, suspending leads SL, frame portions FP, inner leads IL, and outer leads OL. The suspending leads SL support the die pad DP and the frame portions FP. The suspension leads SL have through holes T1 respectively. The frame portions FP surround the suspension leads SL framewise and spacedly from the suspension leads.

The paste portion JP is provided on the lead frame. The paste portion JP is positioned on each of the die pad DP and the suspending leads SL. Parts of the paste portion JP located on the suspending leads SL are positioned respectively between the die pad DP and the through holes T1. The paste portion JP comprises cured resin.

The lower semiconductor chip C1 is mounted on the lead frame through the paste portion JP. When seen in plan, the lower semiconductor chip C1 has a first center line L1 and is disposed so as to overlap the die pad DP and partially overlap the suspending leads SL.

The upper semiconductor chip C2 is mounted on the lower semiconductor chip C1 through a die attach film DF. When seen in plan (FIG. 2), the upper semiconductor chip C2 is positioned on one side (left side in FIG. 2) of the first center line L1. Likewise, when seen in plan (FIG. 2), a second center line L2, which is a center line of the upper semiconductor chip C2, is parallel to the first center line L1 and is positioned on one side (left side in FIG. 2) of the first center line L1. The paste portion JP (FIG. 4) is positioned on both sides of the second center line L2 when seen in plan.

The resin member RS is a sealing member which covers the die pad DP and the lower and upper semiconductor chips C1, C2.

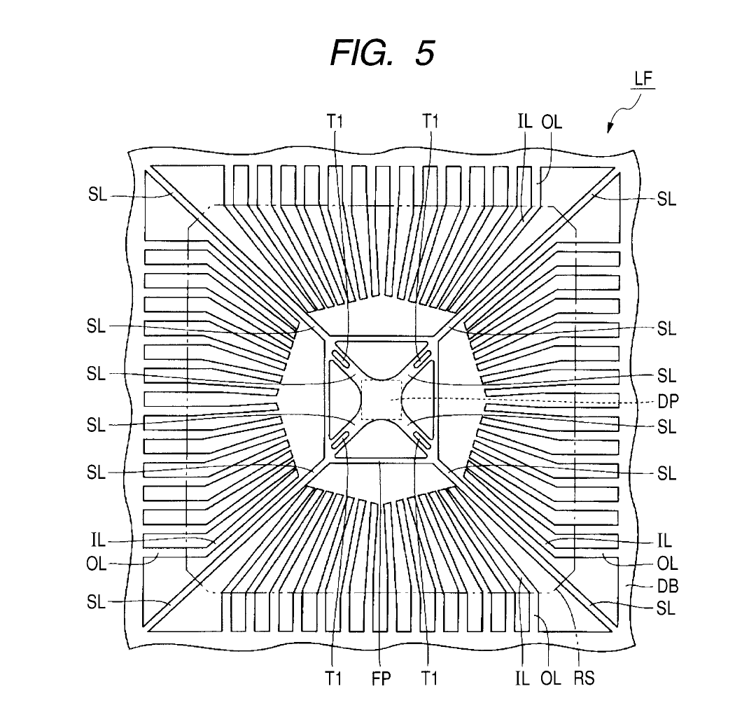

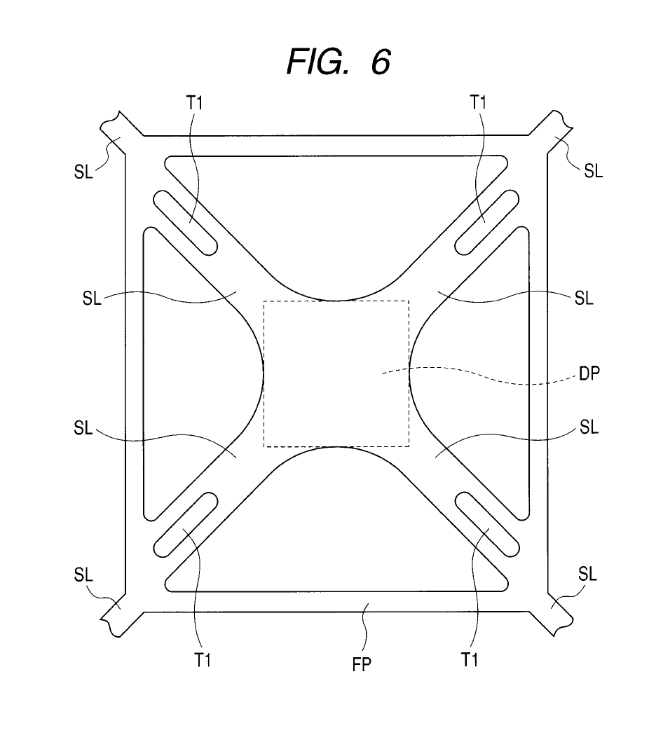

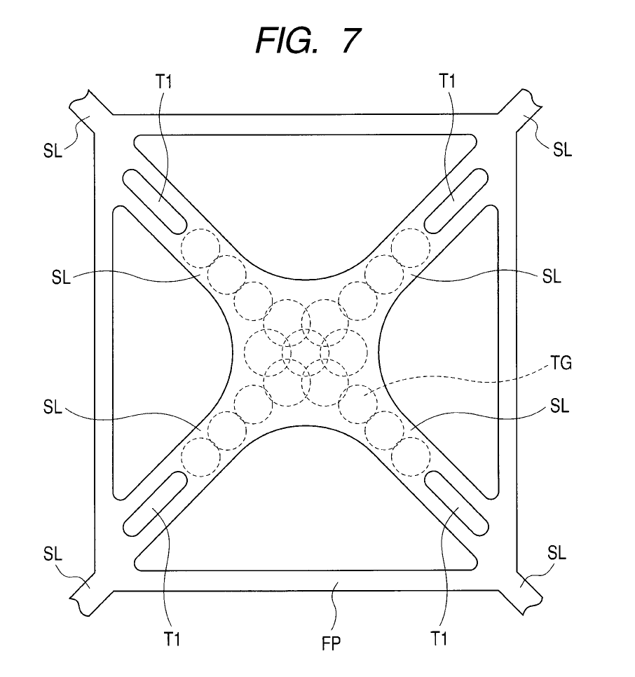

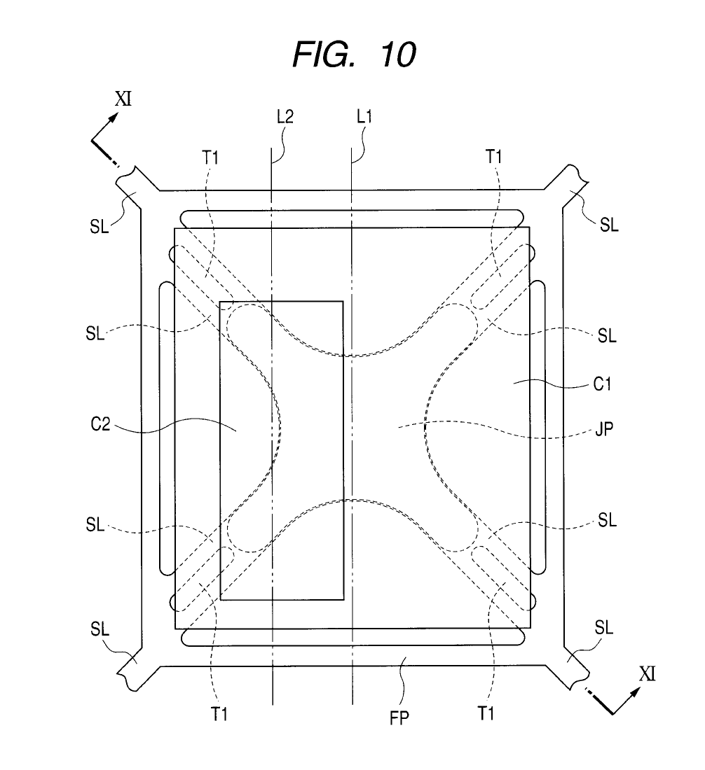

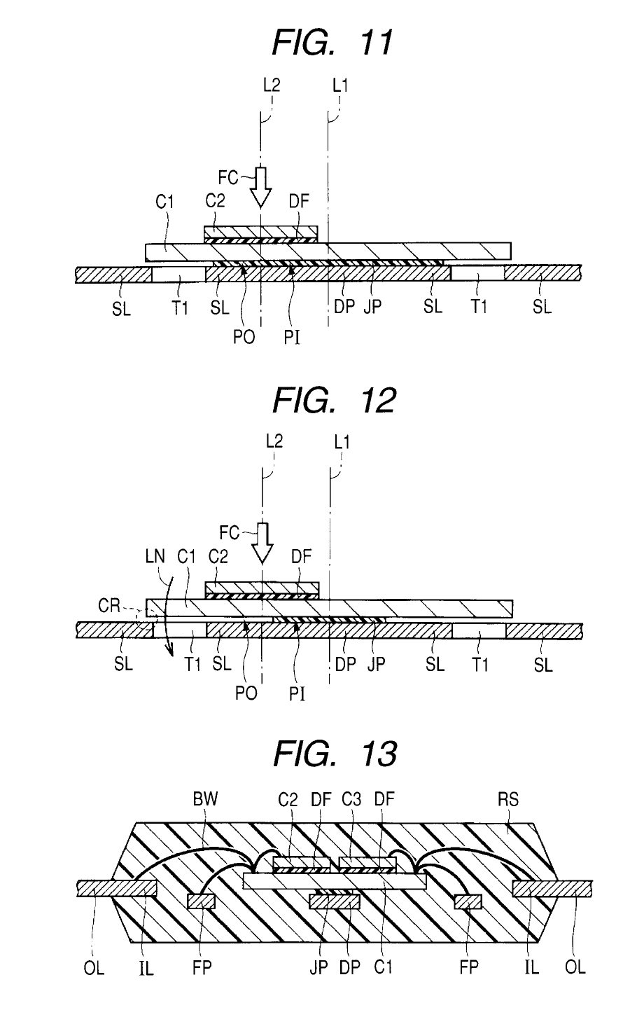

A description will now be given about a method for manufacturing the semiconductor device according to this first embodiment. FIG. 5 is a partial plan view showing schematically a first process in the method for manufacturing the semiconductor device according to this first embodiment. FIG. 6 is a schematic enlarged view of a central portion of FIG. 5. FIGS. 7 to 10 are partial plan views showing schematically second to fifth processes respectively in the method for manufacturing the semiconductor device according to the first embodiment. FIG. 11 is a schematic sectional view taken along line XI-XI in FIG. 10.

Referring to FIGS. 5 and 6, first a lead frame LF is formed. The lead frame LF has dam bars DB.

Referring to FIG. 7, nozzles (not shown) for discharging liquid paste toward regions TG are disposed. The regions TG are positioned on the die pad DP and the suspending leads SL respectively.

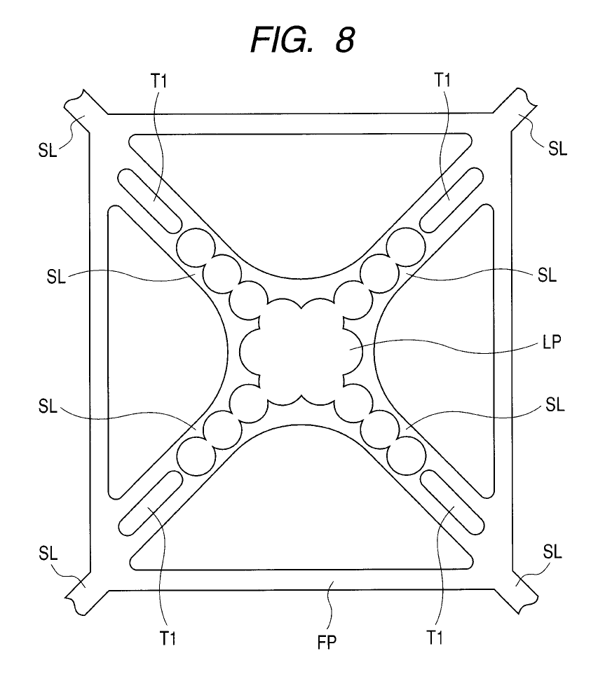

Referring to FIG. 8, with paste being discharged from the nozzles, a liquid paste portion LP is formed on all of the die pad DP and the suspending leads SL.

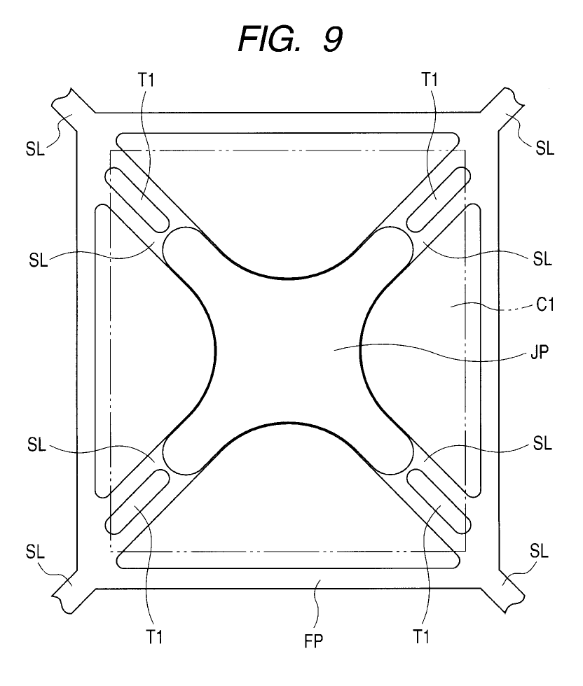

Referring to FIG. 9, a lower semiconductor chip C1 is mounted on the lead frame through the liquid paste portion LP (FIG. 8) so as to overlap the die pad DP and partially overlap the suspending leads SL in plan view. Next, the liquid paste portion LP (FIG. 8) is heat-cured to form a paste portion JP.

Referring to FIGS. 10 and 11, an upper semiconductor chip C2 is pushed onto the lower semiconductor chip C1 at a load FC through a die attach film DF. In this way the upper semiconductor chip C2 is mounted onto the lower semiconductor chip C1. In this case, the upper semiconductor chip C2 is positioned on one side (left side in FIG. 10) of a first center line L1 when seen in plan (FIG. 10). A second center line L2 of the upper semiconductor chip C2, when seen in plan, is parallel to the first center line L1 and is positioned on one side (left side in FIG. 10) of the first center line. The second center line L2 is positioned so that the paste portion JP lies on both sides (arrow PO side and arrow PI side in the drawings) of the second center line.

Referring mainly to FIG. 4, a resin member RS is formed, for example, by a transfer molding method. Next, dam bars DB (FIG. 5) are cut off.

In this way there is produced the semiconductor device of this embodiment. The following description is now provided about a method for manufacturing a semiconductor device as a comparative example. FIG. 12 is a schematic sectional view showing schematically one process in a method for manufacturing a semiconductor device as a comparative example.

Referring to FIG. 12, in this comparative example, unlike the first embodiment, a paste portion JP is provided on only an arrow PI side in the figure of a second center line L2 and is not provided on an arrow PO side. Consequently, the lower semiconductor chip C1 is apt to tilt like an arrow LN in the figure due to the load FC induced at the time of mounting of the upper semiconductor chip C2. As a result of this tilting, a collision between the lower semiconductor chip C1 and a suspending lead SL occurs at a broken-line portion CR in the figure, which may cause cracking or chipping of the lower semiconductor chip C1.

According to this first embodiment, as shown in FIG. 11, not only the paste portion JP lying over the die pad DP but also the paste portion JP lying over the suspending leads SL can support the lower semiconductor chip C1, so that the lower semiconductor chip C1 is supported stably. Consequently, tilting of the lower semiconductor chip C1 is suppressed when the upper semiconductor chip C2 is mounted onto the lower semiconductor chip C1. Thus, it is possible to prevent cracking or chipping of the lower semiconductor chip C1 caused by collision of the lower semiconductor chip C1 with the lead frame.

That is, according to this first embodiment, since the paste portion JP positioned on both sides of the center line L2 in plan can support the lower semiconductor chip C1, the lower semiconductor chip is supported stably. Therefore, tilting of the lower semiconductor chip C1 is suppressed when the upper semiconductor chip C2 is mounted onto the lower semiconductor chip, thus making it possible to prevent cracking or chipping of the first semiconductor chip caused by collision of the lower semiconductor chip C1 with the lead frame.

### Second Embodiment

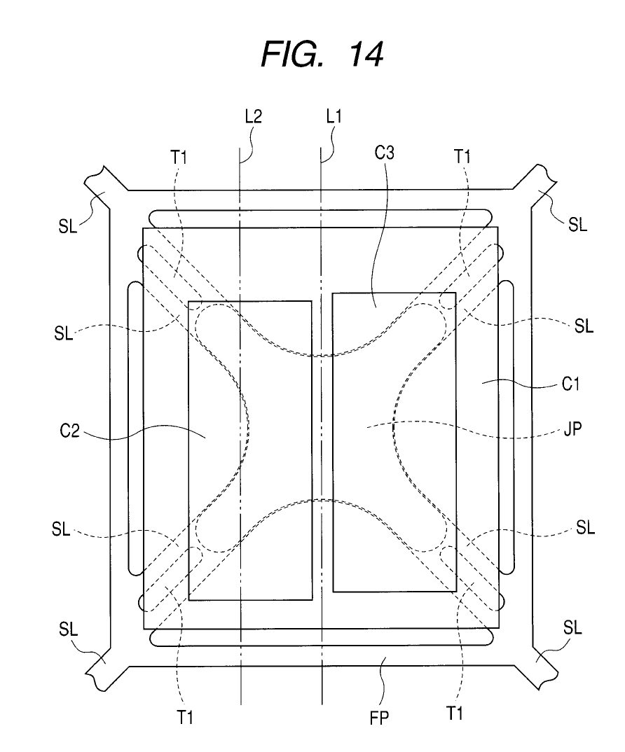

FIG. 13 is a sectional view showing schematically the configuration of a semiconductor device according to a second embodiment of the present invention. FIG. 14 is a partial plan view showing schematically one process in a method for manufacturing the semiconductor device according to the second embodiment. The ranges represented by FIGS. 13 and 14 respectively correspond to the ranges represented by FIGS. 3 and 10 in connection with the first embodiment.

Referring to FIGS. 13 and 14, the semiconductor device of this second embodiment further has an upper semiconductor device C3 over the lower semiconductor chip C1 in addition to the configuration of the semiconductor device of the previous first embodiment. When seen in plan, the upper semiconductor chip C2 is positioned on one side (left side in the drawings) of the first center line L1, and the upper semiconductor device C3 is positioned on the other side (right side in the drawings) of the first center line L1.

Other constructional points than the above are almost the same as in the configuration of the first embodiment described above. Therefore, as to the same or corresponding elements, they are identified by the same reference numerals and explanations thereof will not be repeated.

According to this second embodiment there is obtained the same effect as in the first embodiment. Besides, in addition to the upper semiconductor chip C2, the upper semiconductor chip C3 can be disposed over the lower semiconductor chip C1.

### Third Embodiment

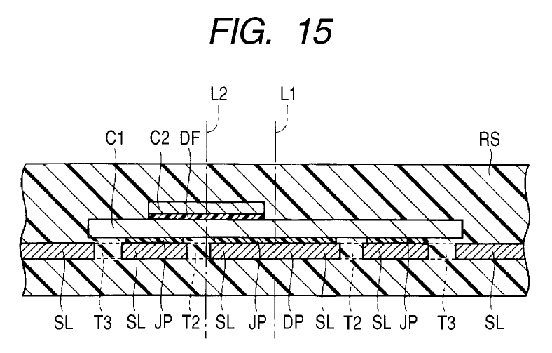

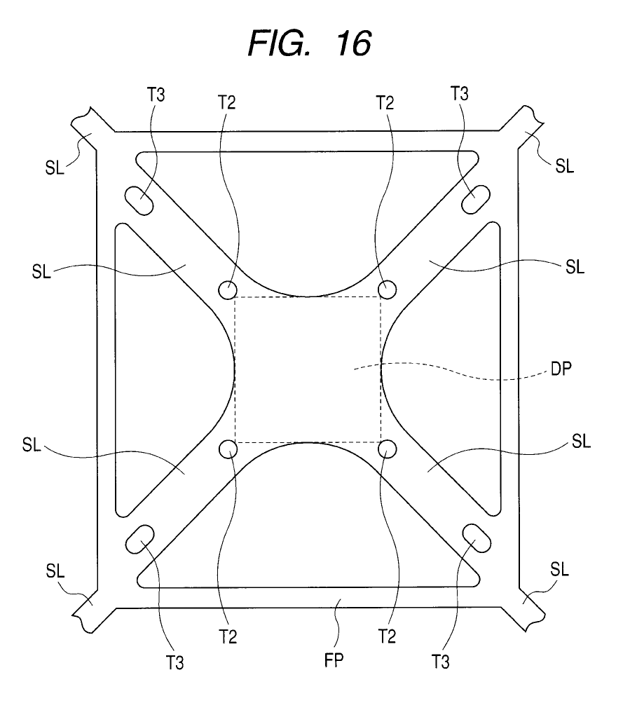

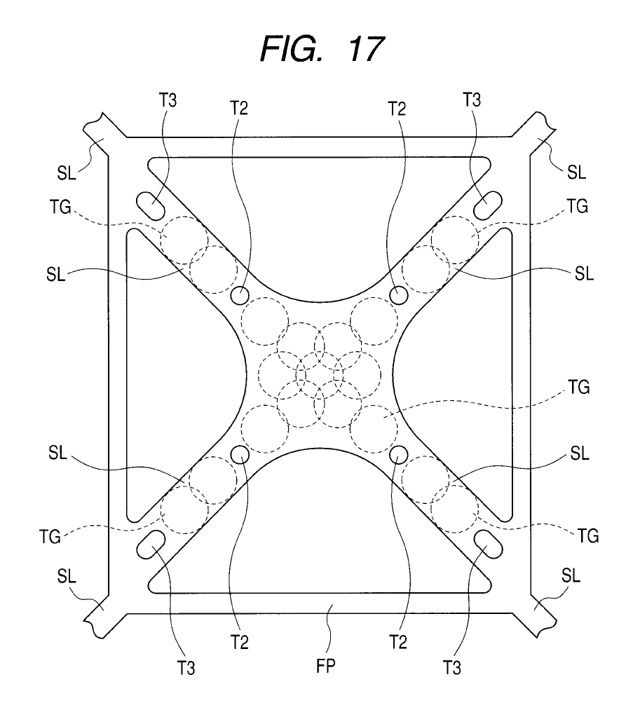

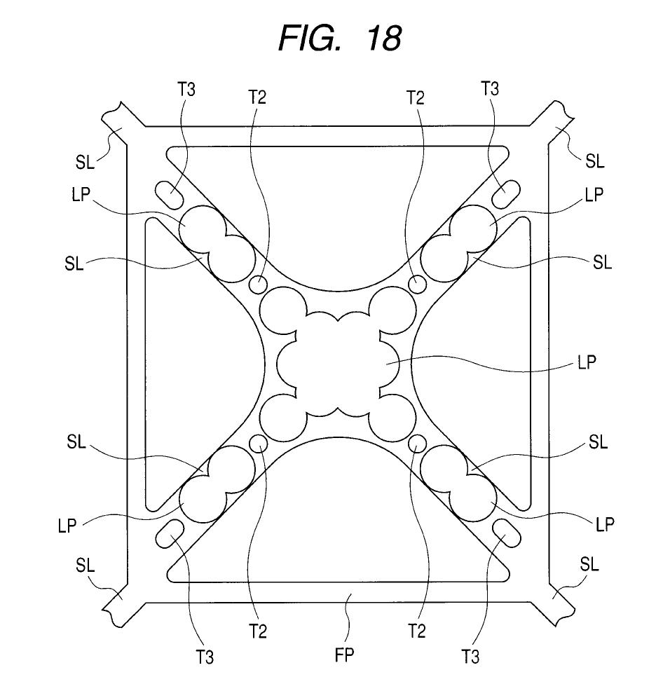

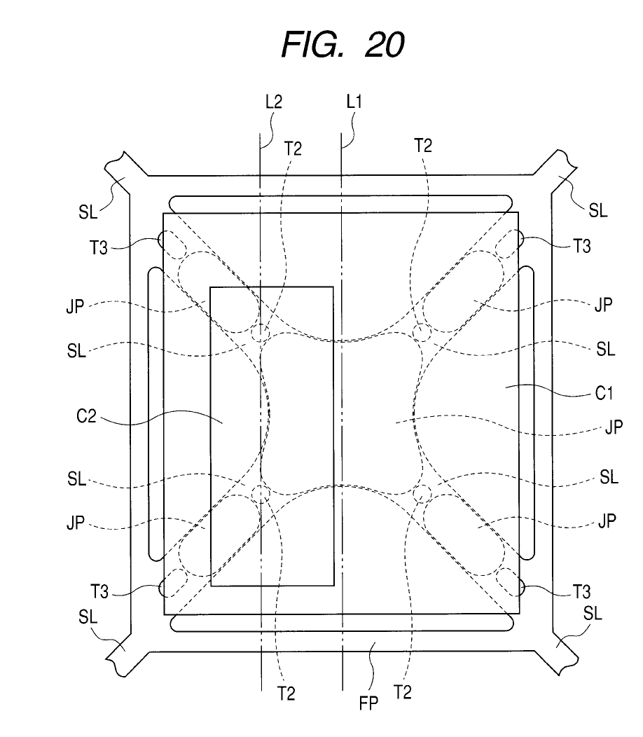

FIG. 15 is a partial sectional view showing schematically the configuration of a semiconductor device according to a third embodiment of the present invention. FIGS. 16 to 20 are partial plan views showing schematically first to fifth processes respectively in a method for manufacturing the semiconductor device according to the third embodiment. The range represented by FIG. 15 corresponds to the range represented by FIG. 4 in connection with the first embodiment. The ranges represented by FIGS. 16 to 20 correspond to the ranges represented by FIGS. 6 to 10 respectively in connection with the first embodiment.

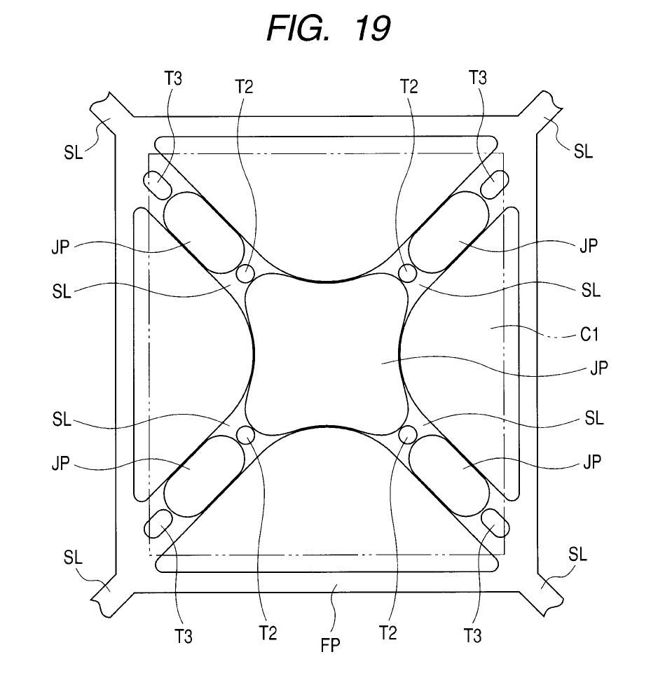

Referring to FIGS. 15 to 20, suspending leads SL used in this third embodiment are each formed with a through hole T2 and a through hole T3 instead of the through hole T1 in the first embodiment. The through hole T2 (FIG. 19) is positioned between a part of the paste portion JP lying on the die pad DP and a part of the paste portion JP lying on the associated suspending lead SL. The through hole T3 is positioned so as to sandwich the part of the paste portion JP lying on the associated suspending lead SL in between it and the through hole T2.

Other constructional points than the above are almost the same as in the configuration of the first embodiment. Therefore, as to the same or corresponding elements, they are identified by the same reference numerals as in the first embodiment and explanations thereof will not be repeated.

According to this third embodiment there is obtained the same effect as in the first embodiment. In each through hole T2 there is formed a portion of direct contact between the resin member RS and the lower semiconductor chip C1. Bonding of this portion is stronger than the bonding between the resin member RS and the suspending lead SL. With this strong bonding, it is possible to suppress the occurrence of peeling of the resin member RS caused by a change in temperature of the semiconductor device. As a result, it is possible to enhance the reliability of the semiconductor device.

It should be understood that the above embodiments are illustrative and not limitative in all points. The scope of the present invention is indicated not by the above description but by the scope of claims and it is intended that meanings equal to the scope of claims and all changes falling under the scope of claims are included in the scope of the present invention.

The present invention is advantageously applicable particularly to a semiconductor device having plural semiconductor chips and a lead frame.

1. A semiconductor device comprising:
a lead frame having a die pad and suspending leads for supporting the die pad;
a joining portion provided over the lead frame;
a first semiconductor chip provided over the lead frame through the joining portion;
a second semiconductor chip provided over the first semiconductor chip; and
a resin member covering the die pad and also covering the first and second semiconductor chips,
wherein the joining portion is positioned over each of the die pad and the suspending leads.

2. A semiconductor device according to claim 1, wherein the suspending leads each includes a through hole formed in a position between a part of the joining portion lying over the die pad and a part of the joining portion lying on the suspending lead.

3. A semiconductor device comprising:
a lead frame having a die pad and suspending leads for supporting the die pad;
a joining portion provided over the lead frame;
a first semiconductor chip provided over the lead frame through the joining portion, the first semiconductor chip having a first center line and being disposed so as to overlap the die pad and partially overlap the suspending leads in plan view;
a second semiconductor chip provided over the first semiconductor chip, the second semiconductor chip having a second center line parallel to the first center line and positioned on one side of the first center line in plan view; and
a resin member covering the die pad and also covering the first and second semiconductor chips,
wherein the joining portion is positioned on both sides of the second center line in plan view.

4. A semiconductor device according to claim 3, wherein the second semiconductor chip is positioned on the one side of the first center line when seen in plan.

5. A semiconductor device according to claim 1, wherein the joining portion comprises cured resin.

6. A semiconductor device according to claim 2, wherein the joining portion comprises cured resin.

7. A semiconductor device according to claim 3, wherein the joining portion comprises cured resin.

8. A semiconductor device according to claim 4, wherein the joining portion comprises cured resin.
